(19) United States
(12) Patent Application Publication
(10) Pub. No.: US 2025/0370331 A1
(43) Pub. Date: Dec. 4, 2025

(54) COMPENSATING THICKNESS VARIATIONS IN SUBSTRATES FOR OPTICAL DEVICES

(71) Applicant: Magic Leap, Inc., Plantation, FL (US)

(72) Inventors: Vikramjit Singh, Pflugerville, TX (US); Kang LUO, Austin, TX (US); Matthew C. TRAUB, Plantation, FL (US); Michael Nevin MILLER, Austin, TX (US); Frank Y. XU, Austin, TX (US); Ryan Jason ONG, Austin, TX (US); Stephen RUGG, Plantation, FL (US); Julie FRISH, Plantation, FL (US); Robert Dale TEKOLSTE, Fort Lauderdale, FL (US)

(21) Appl. No.: 18/872,816

(22) PCT Filed: Jun. 10, 2022
(86) PCT No.: PCT/US2022/072883

§ 371 Date: Dec. 7, 2024

(51) Int. Cl. G03F 7/00; B29D 11/00

(52) U.S. Cl. CPC G03F 7/0005; B29D 11/00442; B29D 11/00663; B29D 11/00769; B29D 11/00951

(57) ABSTRACT

This disclosure describes techniques for fabrication of waveguides as optical devices or for use in optical devices, with the waveguides customized to have a desired thickness variation. Techniques can employ inkjet-based lithography to compensate for thickness variations in the substrate used to manufacture the optical devices, and/or create custom variations in the thickness to achieve various optical properties in the resulting device. In some implementations, a curvature can also be applied to one or both surfaces of the substrate, to achieve desired optical performance and/or enhance fit of a wearable optical device. The optical devices created using the techniques described herein are suitable for use in virtual reality, augmented reality, and/or other suitable optical applications. The optical devices may be created on flexible (e.g., polymer) or more rigid (e.g., glass) substrates, with the thickness of the substrate being customizable using a jettable and curable polymer resin or photoresist.

### TECHNICAL FIELD

The implementations described herein generally relate to systems and methods for modifying substrates used to fabricate surface relief waveguides for eyepieces, and to the optical devices created thereby.

### BACKGROUND

When manufacturing waveguides, eyepieces, and other types of optical devices, performance considerations are generally balanced against cost of the component materials, manufacturing, and testing. Often, high-performance optical devices require materials and manufacturing processes that are time-intensive and/or labor-intensive, and therefore expensive. Traditionally, entities seeking to manufacture high-quality optical devices for commercial sale, industrial use, and/or other purposes have sought to reduce manufacture costs while still maintaining sufficiently high performance standards for the intended use of the devices.

### SUMMARY

This disclosure generally describes methods and systems for reliable fabrication of high-quality surface relief waveguides for eyepieces, using preferably a low-cost material such as a polymer for the substrate of the waveguides. In particular, this disclosure described techniques for manufacturing waveguides using low-cost polymer, including operations to compensate for thickness variation and/or other irregularities in the incoming substrate material, such that the resulting manufactured optical device is of high quality with desired optical performance characteristics.

Implementations include a method performed by a system for manufacturing optical devices, the method including: measuring variation in a thickness of at least a portion of a substrate that is provided as input to the system; based on the measured variation in the thickness of the substrate, determining a drop pattern for applying a fluid to at least the portion of the substrate, wherein the drop pattern reduces the variation in the thickness in at least the portion of the substrate; and applying the drop pattern to at least the portion of the substrate, including dispensing the fluid onto the substrate according to the drop pattern and curing the fluid.

In some implementations, the substrate is composed of a polymer. In some implementations, the substrate is composed of a glass (e.g., sapphire). In some implementations, the substrate is composed of one or more of polycarbonate, polyethylene terephthalate, or polyethylene naphthalate.

In some implementations, the fluid is a polymer resist.

In some implementations, the fluid and the substrate have substantially a same refractive index.

In some implementations, curing the fluid includes one or more of applying ultraviolet radiation to the dispensed fluid, or applying heat to the dispensed fluid.

In some implementations, determining the drop pattern includes selecting the drop pattern from a plurality of different drop patterns stored in a drop pattern library, wherein each of the plurality of different drop patterns corresponds to a respective variation profile, and wherein the drop pattern selected based on its correspondence to the variation profile corresponding to the measured variation.

In some implementations, measuring the variation in the thickness of at least the portion of the substrate includes performing at least one of interferometry or reflectometry to measure the variation.

In some implementations, applying the drop pattern is performed by the system during a phase of processing the substrate that is subsequent to an earlier phase during which the system measures the variation in the thickness of at least the portion of the substrate.

In some implementations, the method for includes creating one or more diffraction gratings on the portion of the substrate; and singulating the substrate to separate the portion as an optical device.

In some implementations, the one or more diffraction gratings include one or more of an in-coupling grating (ICG), an orthogonal pupil expander (OPE), an exit pupil expander (EPE), or a combined pupil expander (CPE).

In some implementations, creating the one or more diffraction gratings is performed by the system prior to measuring the variation in the thickness and applying the drop pattern.

In some implementations, creating the one or more diffraction gratings includes: dispensing the fluid onto the portion of the substrate; applying at least one template to the dispensed fluid to pattern the dispensed fluid according to the one or more diffraction gratings; and curing the dispensed fluid to create the one or more diffraction gratings.

In some implementations, measuring the variation in the thickness, applying the drop pattern, creating the one or more diffraction gratings, and singulating the substrate are performed by the system as inline operations on the substrate input to the system.

In some implementations, creating the one or more diffraction gratings and applying the drop pattern are performed by the system in a same operation of dispensing the fluid, applying the at least one template, and curing the dispensed fluid.

In some implementations, the method includes shaping at least one surface of the portion of the substrate into a curved shape, by applying one or more of pressure, heat, or a surface contact mold to the portion of the substrate.

In some implementations, the drop pattern is applied to a first side of the portion of the substrate, and the one or more diffraction gratings are created on a second side of the portion of the substrate that is opposite the first side.

In some implementations, the drop pattern is applied to a same side of the portion of the substrate as the one or more diffraction gratings.

In some implementations, the substrate is input to the system in a form comprising one or more of a roll, a sheet, a web, a web roll, or a wafer.

Implementations include an optical device that includes: a substrate that exhibits a first thickness variation across a region of the optical device; and an overlay applied to the region of the optical device, the overlay exhibiting a second thickness variation that compensates for the first thickness variation such that a combined thickness variation in the region is less than the first thickness variation.

In some implementations, the substrate is composed of a polymer. In some implementations, the substrate is composed of a glass. In some implementations, the substrate is composed of one or more of polycarbonate, polyethylene terephthalate, or polyethylene naphthalate.

In some implementations, the overlay is composed of a polymer resist.

In some implementations, the substrate and the overlay have substantially a same refractive index.

In some implementations, the optical device further includes one or more diffraction gratings on at least one surface of the optical device.

In some implementations, the one or more diffraction gratings include one or more of an in-coupling grating (ICG), an orthogonal pupil expander (OPE), an exit pupil expander (EPE), or a combined pupil expander (CPE).

In some implementations, at least one surface of the optical device is curved.

In some implementations, the first thickness variation is a local thickness variation or a total thickness variation.

Other features and advantages are apparent from the following detailed description and figures, and from the claims.

### BRIEF DESCRIPTION OF THE DRAWINGS

FIG. 1 depicts an example system for manufacturing optical devices.

FIG. 2 depicts a flow diagram of an example process for manufacturing optical devices.

FIGS. 3A, 3B, and 4 depict schematics of example optical devices.

FIGS. 5A and 5B show images of example thickness measurements.

FIG. 6 show example test results of an optical device.

FIG. 7 depicts an example computing system.

### DETAILED DESCRIPTION

This disclosure describes various implementations of methods and systems for manufacturing high-quality optical devices, and various embodiments of the manufactured optical devices. In particular, this disclosure describes techniques for the fast and/or low-cost fabrication of flexible waveguides as optical devices or for use in optical devices. Using the techniques described herein, the waveguides can be customized with a tailored local thickness variation (LTV) and/or total thickness variation (TTV). In some implementations, the techniques employ inkjet-based lithography to compensate for thickness variations in the substrate used to manufacture the optical devices, and/or create custom variations in the thickness to achieve various optical properties in the resulting device. Implementations also support a manufacturing step to impose a curvature on the substrate, for example to give the result optical device some optical power or other optical performance effect, and/or to enhance fit or comfort of a wearable optical device. The optical devices created using the techniques described herein are suitable for use in virtual reality (VR), augmented reality (AR), and/or mixed reality (MR) systems, and/or other suitable optical applications. The optical devices may be created on flexible (e.g., polymer) or more rigid (e.g., glass) substrates, such that the LTV and/or TTV of the substrate is customizable using a jettable and curable polymer fluid, such as a resin or photoresist.

The techniques can be applied to quickly manufacture inexpensive waveguides using substrate that is provided in a roll, or precut in a sheet or wafer format. For example, the substrate may be supplied to a manufacturer in the form of a low-cost film, roll, and/or sheet of a polymer, such as a polycarbonate. Such a substrate may have a low index of refraction. For example, polycarbonate may have an index of 1.60 at 455 nanometers (nm) (e.g., blue) wavelengths of light, an index of 1.59 at 530 nm (e.g., green), and an index of 1.58 at 640 nm (e.g., red). Such low-cost substrate material may arrive having considerable variation in its thickness (e.g., LTV and/or TTV) across regions of the substrate. Accordingly, an optical device manufactured using such a substrate may have undesirable optical properties given its non-uniformity in thickness, or at least given its irregularity or unpredictability in thickness. Traditional methods of manufacture are not suitable to exploit such low cost, low index films as polycarbonate, while still ensuring that the resulting optical device (e.g., waveguide) has suitable key performance indicators (KPIs) comparable to those achieve using glass substrate. The techniques described herein provide a method to compensate for thickness variations across the substrate during the manufacture of optical devices, providing for sufficiently high quality in the resulting device while still exploiting the low-cost and easily manipulated polymer substrate.

The techniques described herein allow for the fast creation of low cost waveguides using imprinted relief structures to compensate for incoming thickness variations in the substrate that is input to manufacturing. The substrate can be a polymer, such as polycarbonate, polyethylene terephthalate, polyethylene naphthalate, and so forth. The substrate material can come in a roll, a sheet, a film, or other suitable form. The substrate material may already be cut to the desired shape and size for an optical device (e.g., waveguide or eyepiece), or it may come in a roll or sheet that can be cut (e.g., singulated) to the desired shape and size during manufacture. By imprinting the raw substrate with a polymer resist to compensate for thickness variations in the incoming substrate material, optical devices can be manufactured with the LTV and/or TTV to ensure sufficiently high quality for optical KPIs such as sharpness, uniformity, efficiency, etc. in the operation of the resulting device. Use of polymer substrates such as polycarbonate films, for example at index of approximately 1.59, can reduce the field of view of the resulting device compared to using of index=2.0 glass substrate, such as when the resulting device is used as a waveguide to convey and direct light toward a user's eye (e.g., in an AR headset). However, in instances where a 40° by 30° field of view is acceptable, for example, then such substrate films with such an index of refraction may be suitable. In instances where the manufactured waveguides are employed in a stack of waveguides in an eyepiece, e.g., with each waveguide conveying a different color of the light, there may be cross talk of the three different colors between the waveguides patterned with different pitches, there may be an improvement in field of view such that the horizontal field of view can be increased to over 40°. If polymer substrates of other polymer classes are employed, such as cyclic olefin polymers (COP) or cyclic olefin copolymers (COC), use of such polymers may provide improvements related to substrate clarity, in terms of improved haze and internal transmittance.

As used herein, optically transparent generally refers to the physical property of allowing at least some wavelengths of light to pass through a material without being scattered or absorbed. As used herein, a high refractive index generally refers to a refractive index (n) (e.g., of an imprinted polymer resist) that greater than 1.6 or 1.7. In one example, a high refractive index refers to n greater than 1.6 or 1.7 and less than 1.9.

As used herein, TTV refers to the difference between the maximum and minimum values of the thickness of a substrate in a series of point measurements across a dimension of a substrate. For a substrate having a patterned surface (e.g., an optically active diffraction grating), the TTV refers to an approximation assessed by ignoring contributions of pattern features to the thickness. For example, a thickness (or height) of a typical feature on a patterned substrate may be in a range of approximately 10 nanometers (nm) to 150 nm. That thickness is governed by the trench depth of the template, which can vary by 10% (e.g., 1 nm to 15 nm). Accordingly, the thickness of a patterned substrate assessed at a location that includes a protrusion can be approximated by subtracting a given feature thickness from the assessed thickness to yield an adjusted thickness, while thickness of a patterned substrate assessed at a location without a protrusion is unchanged. That is, the adjusted (e.g., reduced) thickness of a feature area and a native thickness of an unpatterned area can be used to calculate TTV for a substrate having a patterned surface. As used herein, LTV refers similarly to a difference between the maximum and minimum value of the thickness of a substrate, across a smaller area or region of the substrate compared to a TTV measurement.

The examples herein discuss adjusting the thickness of the substrate to avoid adverse optical performance caused by irregularities of the raw substrate used to manufacture waveguides or other optical devices. Adjusting the thickness can include adjusting the physical thickness of the substrate (e.g., to make it more uniformly flat and/or thick over a portion of its surface). Adjusting the thickness can also be described as adjusting the optical thickness of the substrate, that is a measure of the thickness that effects the (e.g., virtual image) light being incoupled into, conveyed through, and outcoupled from the waveguide, as well as the world light coming into the waveguide from the world.

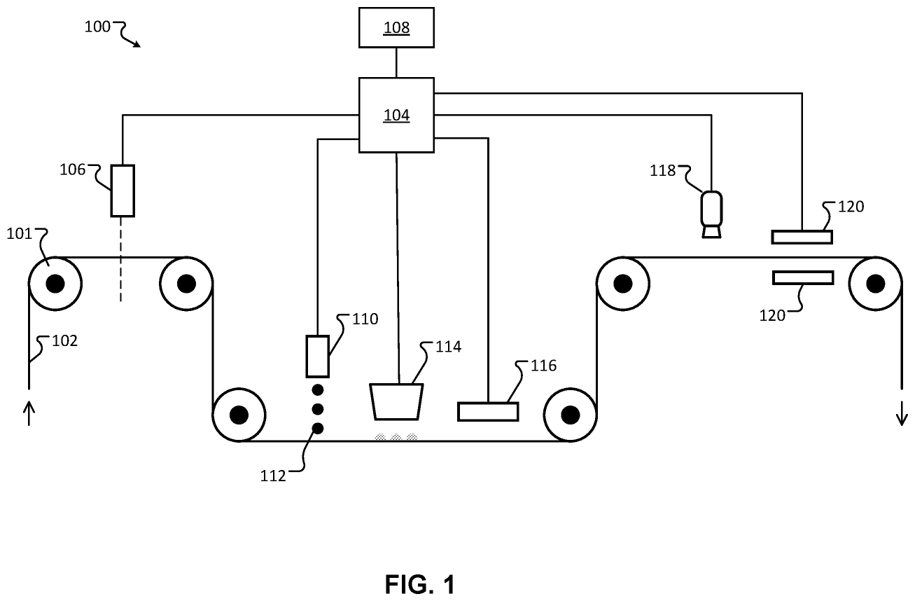

FIG. 1 depicts an example system 100 for manufacturing optical devices. As shown in this example, the system 100 can include various components that perform various operations to manufacture an optical device, such as a waveguide or an eyepiece. The system 100 can receive, as input, a substrate material 102. In the example shown the substrate 102 is input in the form of a roll, such as a rollable, bendable polymer material. The various rollers shown represent an example of a mechanism that moves the sheet of substrate 102 between various positions in the system 100 where different operations may be performed. Other suitable mechanisms for moving the substrate between operations may also be used, such as a moveable stage or chuck. Moreover, implementations are not limited to processing the substrate 102 in a rollable sheet form as shown. The substrate 102 may also be input to the system 100 in the form of a film or sheet, which may have been previously cut to the desired shape and size. In such instances, the pieces of substrate 102 may be moved from operation to operation using a chuck or stage that moves between stations, or the substrate 102 may remain stationary as the various other components are moved into position proximal to the substrate 102 to perform their various actions. As described herein, the substrate 102 may be composed of a flexible material, such as a polymer.

The system 100 can include a control device 104, such as a computer, that monitors operations of the various components of the system 100 and sends signals to the various components to control their operations. The control device 104 may be any suitable type of computing device, and may be multiple computing devices. The control device 104 may be physically situated in proximity to other components of the system 100, or may be remote from the rest of the system 100. The control device 104 may communicate with the other components over one or more networks of any suitable type.

The system 100 can include a thickness measuring device 106, such as a (e.g., laser) interferometer or reflectometer. The device 106 can operate to measure the thickness variation over a portion of the substrate 102 that is under or otherwise in proximity to the device 106 as the substrate 102 moves through the system 100. Any suitable thickness measuring technique may be employed. The thickness measurements may also be described as a thickness map of a portion of the substrate 102.

The thickness data generated by the device 106 can be communicated to the control device 104. The control device 104 may analyze the thickness data and determine a drop pattern to apply to the substrate 102. As described herein, the drop pattern may be determined to compensate for thickness variation in the measured portion of the substrate. For example, the drop pattern may be determined such that when the drop pattern is applied to the substrate 102, the modified substrate has a more uniform thickness over the measured portion than it had previously. In this way, the application of the drop pattern can correct the incoming flaw or inconsistency in the substrate 102, and enable the substrate 102 to be used for manufacture of high-quality optical devices. In some implementations, the drop pattern may be determined to intentionally apply a more pronounced and/or more regular thickness variation to the substrate 102 than that exhibited by the incoming, unmodified substrate 102, for example to achieve certain desired optical effects.

In some implementations, the drop pattern can be determined through reference to a plurality of possible drop patterns stored in a pattern library 108 that is communicatively coupled to the control device 104. For example, the pattern library 108 may be a database that stores a mapping between thickness variations and drop patterns. The control device 104, on receiving the thickness variation information from the device 106, can determined that the thickness variation pattern on the portion of the substrate 102 matches, or is sufficiently similar to, one of the stored thickness variation patterns. The control device 104 can then retrieve, from the pattern library 108, the drop pattern that matches, or is sufficiently similar to, the measured thickness variation.

The determined drop pattern can be communicated to a dispensing device 110 that dispenses one or more drops of fluid 112 onto the substrate 102 according to the drop pattern. In some implementations, the dispensing device 110 may be a printhead and/or jetting device that deposits fluid drops of a determined size onto determined locations on the surface of the substrate 102. In some implementations, the dispensing device 110 employs a drop-on-demand Jet and Flash Imprint Lithograph (J-FIL) technique to dispense the fluid 112. Such techniques are described in U.S. Pat. No. 7,077,992, titled “Step and Repeat Imprint Lithography Processes,” the entirety of which is incorporated by reference into the present disclosure. Though not shown in the example of FIG. 1, the system 100 may also include suitable components to circulate and store the fluid 112, and convey the fluid 112 to the device 110.

In some implementations, the fluid 112 is a resin or photoresist (also described as a resist) that is transparent to light. The fluid 112 may be a polymer, and may have an index of refraction that matches, or is sufficiently similar to that of the substrate 102, to minimize undesirable reflection or refraction when light encounters the boundary between the cured fluid 112 and the substrate 102 in the finished optical device. In this context sufficiently similar refraction index indicates that the difference, if any, between the refraction indexes of the fluid 112 and the substrate 102 is within a predetermined tolerance. For example, the difference between the indexes may be kept to less than 0.2, less than 0.1, or less than 0.05. In this way, to the extent possible, implementations operate to correct the original flaws (e.g., thickness variations) present in the incoming substrate 102, without introducing adverse optical effects that may introduce flaws into the manufactured optical device.

After the fluid 112 is dispensed, in some implementations a template 114 may be applied to the dispensed fluid 112 to form the dispensed fluid 112 into the desired shape on the surface of the substrate 102. In some implementations, a curing device 116 may operate to then cure the fluid 112. Such curing may be through application of heat, radiation (e.g., ultraviolet), pressure, and/or through other suitable techniques.

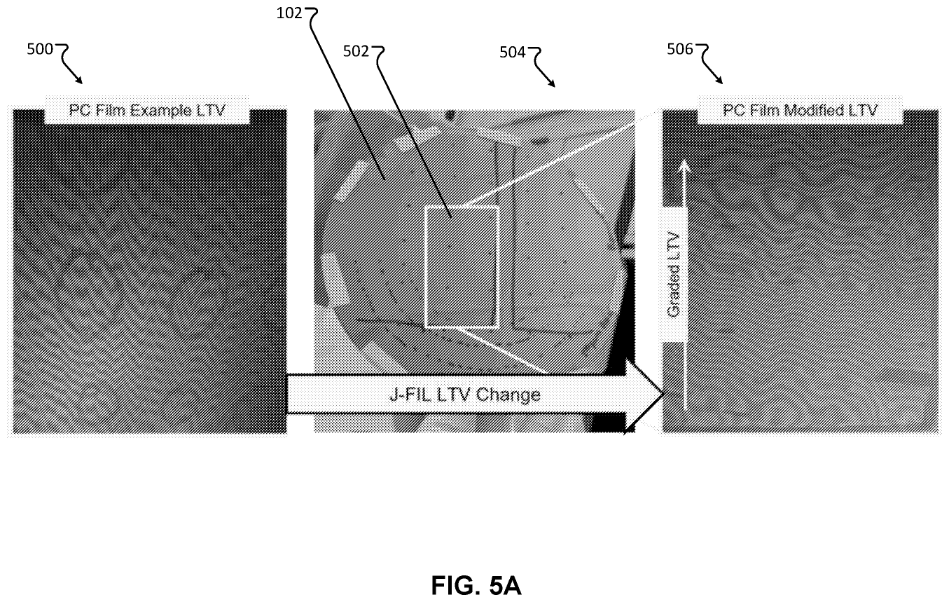

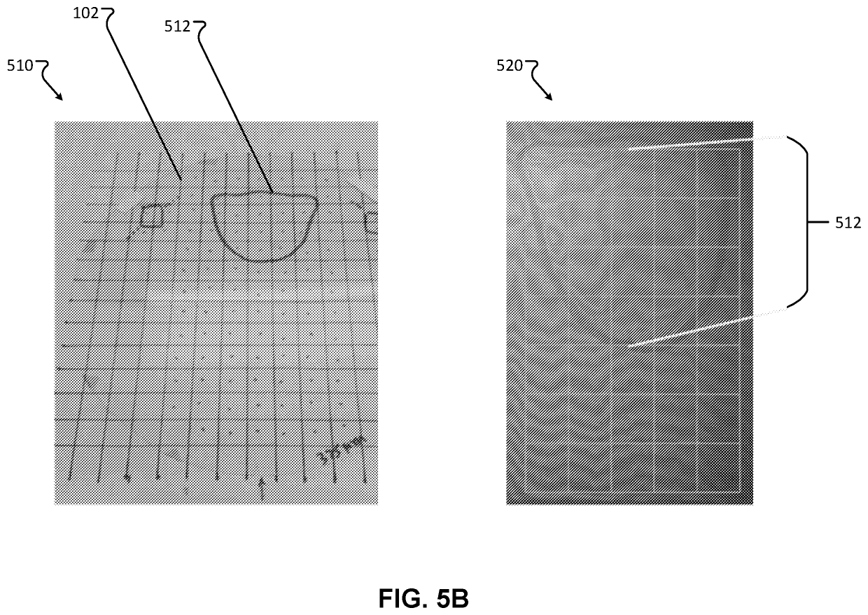

At this stage, the incoming thickness variation in the substrate 102 may be substantially corrected or at least sufficiently reduced. In some implementations, the system 100 can include an inspection device 118 that collects data regarding the modified substrate 102. The inspection device 118 may determine the degree to which the thickness variation has been corrected. In some implementations, the inspection device 118 is a thickness variation measurement device, such as an interferometer or reflectometer. For example, the in-situ inspection system can include a laser source with a magnifying diverging lens collimator attachment through a beam splitter, in which the interference light is captured over a large area from the original optical path as well as from a back reflection off the target substrate surface. Such a thickness variation measurement is shown in the example of FIG. 5A.

In some implementations, the system 100 can include a curvature application device 120 that imparts a curvature to at least a portion of the substrate 102, such as the portion that has been thickness-corrected. For example, in instances where the substrate 102 is a polymer, the device 120 can include one or more molds that, which pressed against the substrate 102, shape the substrate 102 into a curved shape. Such curvature can be imparted to one side of the substrate 102 or both sides of the substrate 102. For example, the top of the substrate 102 can be shaped to be convex, using a mold that is concave in shape. In addition, or alternatively, the bottom of the substrate 102 can be shaped to be concave, using a mold that is convex in shape. A concave bottom shape, used in addition to a convex top shape, can provide negative world light power while preserving a desired TTV and/or LTV in the waveguide. The imparted curvature may give the manufactured optical device (e.g., eyepiece, waveguide) some additional optical power, or provide other optical performance as described below. In generally, the device 120 may operate to shape the substrate 102 into any desired shape, and may be useful for creating an optical device of a suitable shape for a wearable device (e.g., to better fit a wearer's head and/or eye region). The ability to easily shape a polymer substrate 102 to add optical power, provide a depth plane for projected virtual objects, optimize wearability, and/or for aesthetic purposes, is an advantage provided the polymer substrate 102. The shaping may be through use of molds that contact the substrate 102, or through some other technique that does not involve contacting the surface of the substrate 102. The latter may be useful in implementations where the shaping step is performed after the creation of optically active regions (e.g., diffraction gratings) on the surface of the substrate 102, as described below.

In some implementations, the system 100 can also include other components and/or stations that perform other actions on the substrate 102. For example, the system 100 can include other components to perform another phase of jetting drops of resist, imprinting using template(s), and curing the resist, to create one or more optical active regions on one or both surfaces of the substrate 102. This step may create diffraction gratings in one or more regions of the substrate 102, such as an one or more of an in-coupling grating (ICG), an orthogonal pupil expander (OPE), an exit pupil expander (EPE), or a combined pupil expander (CPE). In some implementations, the creation of such diffraction gratings may be performed through operation of the same devices 110, 114, and/or 116 that performed the thickness variation correction. The system 100 can also include a device that singulates (e.g., cuts) the substrate 102 into desired shape for the optical device.

As shown in the example of FIG. 1, the processing of the substrate 102 can include performing the various actions to correct for thickness variation, create diffraction gratings, apply curvature, and/or singulate the optical device through the continuous operation of the system 100 on a continuous sheet of the substrate 102. In such implementations, a continuous sheet of substrate 102 can be fed into the system 100 (e.g., on the left side of FIG. 1) and emerge (e.g., from the right side of FIG. 1) as finished optical devices that have been thickness-corrected, imprinted with diffraction gratings, singulated, and/or curved or otherwise shaped according to the intended design of the finished optical device.

The operations described may be performed in any suitable order, and/or combined in some instances. For example, the shaping of the substrate 102 may be performed prior to the creation of diffraction gratings. As another example, the diffraction grating(s) may be created in a same imprinting (e.g., J-FIL) process as the thickness correction. Singulation may be performed at any suitable time before or after the imprinting steps and/or the shaping step.

Although examples herein may describe the substrate 102 as a polymer substrate, implementations are not so limited. In some examples the substrate is composed of a glass, such as sapphire with a refractive index in the range of approximately 1.5 to 1.75. In such instances, the dispensed fluid (e.g., resin) can substantially match this index of the substrate, and be applied to compensate for LTV variation to achieve LTV that is desired for light propagation. Glass having an index of approximately 1.5 to 1.6 can be supplied in a thin roll similar to that of polymer. Implementations support glass or polymer substrate that is supplied in any suitable form, including wafer, sheet, web, web roll, roll, and so forth.

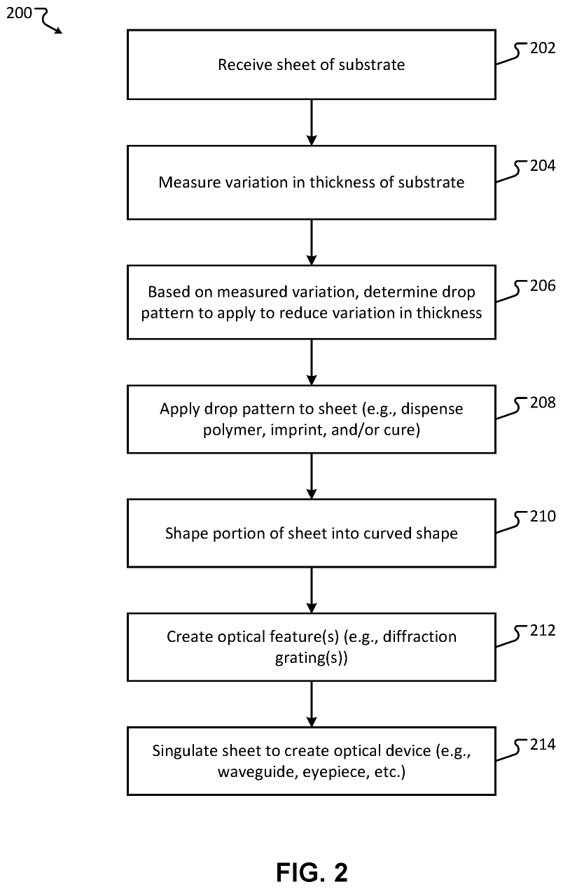

FIG. 2 is a flowchart illustrating an example process 200 for fabrication of an optical device. Operations of the process may be performed by one or more components of the system 100, for example under control of the control device 104. The various operations can be performed in any suitable order. Some operations may be combined into a single operation. Operations may be performed serially and/or in parallel, as suitable for the particular operations.

At 202, a sheet of substrate 102 is received. The substrate 102 may be composed of any suitable material. For example, the substrate 102 may be a polymer as discussed above, and may be transparent and suitable for use as an optical waveguide.

At 204, a measurement is made of the variation in the thickness of at least a portion of the sheet of substrate 102. Such measurement may measure the thickness variation in the region of the substrate 102 where the optical device (e.g., eyepiece, waveguide) is to be cut from the substrate 102. As described above, the measurement may be made using (e.g., laser) interferometry, reflectometry, or some other suitable technique.

At 206, a drop pattern is determined based on the measured thickness variation. As described above, the drop pattern may be selected or otherwise determined to reduce a variation in thickness of the substrate 102. Additionally, or alternatively, the drop pattern may also be selected to impart a determined thickness variation to the substrate 102, for example to provide certain optical effects and/or performance in the final optical device. As discussed above, the drop pattern can be selected from a library of drop patterns, based on which stored drop pattern mostly closely corresponds to the measured thickness variation in the substrate 102.

At 208, the drop pattern is applied to the substrate 102. As described above, such application can include dispensing, imprinting, and/or curing of the resist fluid 112. In some implementations, the substrate 102 is mapped to determine the substrate's LTV in the region where the optical device is to be formed after singulation. The measured thickness variation (e.g., the fringe pattern determined through interferometry) can be mapped back to a thickness variation profile that corresponds to a drop pattern. The drop pattern can be inkjetted or otherwise dispensed and then cured to amplify or negate the LTV profile of the incoming substrate 102. For example, the drop pattern can indicate where additional resist drop volume is to be added or subtracted to the region, to compensate for a specific, measured LTV. Such compensation can enhance optical performance properties of the finished optical device, such as image uniformity, efficiency, and so forth.

At 210, in some implementations, a curvature or other shape is imparted to the substrate 102, to one or both sides of the substrate 102. Such shaping can be achieved through use of one or more molds, application of heat and/or pressure, and/or through other techniques, and may use techniques that contact the substrate surface or that avoid contacting the substrate surface.

At 212, one or more regions of optical feature(s) can be created on one or both surfaces of the substrate 102. Such optical feature(s) can include diffraction grating(s), such as EPE, OPE, ICG, CPE, and so forth. The waveguide surface relief pattern of a desired tone can be imprinted from a template, which may be substantially rigid (e.g., made of glass, silicon, etc.) or which may be more thin and flexible (e.g., a nickel shim, etc.). The imprint may be to the substrate made of a polymer (or glass). The substrate can be in a circular wafer form, a square or rectangular sheet form, a roll form, or other suitable form. The imprint material can be a fluid that is a curable (e.g., acrylate, epoxy, etc.) polymer resist of a selected index range (e.g., approximately 1.5-1.9). As discussed above, the dispense method may be a version of J-FIL. Other suitable methods can be used, including but not limited to inkjetting, spraying, spincoating, slot-die, knife edge coatings, and so forth. The polymer resist can be dispensed on either the surface of the template (e.g., superstrate) or the substrate.

At 214, the sheet of substrate 102 may be singulated (e.g., cut) to the desired shape and size to create the optical device, such as a waveguide or eyepiece.

At this stage, the optical device (e.g., waveguide) has been thickness-corrected or otherwise had its thickness adjusted, and has been patterned to include optically functional features such as diffraction gratings with various nanofeatures. In some implementations, the thickness compensation may be applied to a same side as the diffraction grating(s). Alternatively, the thickness compensation can be applied to a different side of the substrate 102 opposite the diffraction grating(s). In some instances, the diffraction grating(s) can include grating(s) on both sides of the substrate 102, and the thickness compensation can be applied to one or both sides. For example, a waveguide may have the front side patterned with functionally diffractive nanofeatures, and the back side can be used to create a blank conformal film coatings of the desired profile that is created through a selected drop pattern to reduce a primary, undesirable LTV profile and/or add a secondary, desired LTV profile for specific optical properties. The LTV mapping and blank coating can be performed prior to imprinting diffraction grating(s) on either side, for example in the case of a double-sided patterned eyepiece design.

The process may also include a manufacturing step to stack waveguides to form a waveguide stack to include in the optical device, and/or other steps to assemble the device. For example, the optical devices (e.g., eyepieces) can be singulated and stacked and/or assembled as desired from the thickness-corrected, imprinted, curved, and/or singulated functioning waveguides, and stored in rolls, sheets or wafer formats as appropriate.

As discussed above, the fluid dispense, imprinting, and curing to perform he thickness compensation may be combined with the fluid dispense, imprinting, and curing to generate the diffraction grating(s) on the substrate 102. In some implementations, the drop pattern determined to compensate for thickness variation may be combined with the drop pattern designed to create the desired diffraction grating(s). The fluid dispense can be performed according to the combined drop pattern, followed by imprinting and/or curing to set the resist in its desired form.

As discussed above, at one or more phases in the process, the substrate 102 may be inspected by capturing images of the substrate and/or through other techniques. For example, after the thickness compensation step is performed, image(s) of the substrate may be captured and analyzed to determine the effectiveness of the thickness compensation. In some examples, another thickness variation measurement may be performed, as in step 204. Such measurements may be compared to the pre-compensated substrate, as a “before” and “after” view of the substrate 102 to gauge the effectiveness of the thickness adjustment.

Various modifications may be made to this method of mapping and adjusting the LTV to create further enhanced performance in the finished optical device. The dispense of the (e.g., polymer) fluid can be performed using inkjetting, spincoating, slot-die coating, atomization, and/or other suitable techniques. The polymer layer can be deposited as two layers. A first layer can be deposited for thickness compensation of the substrate, which may serve to create an anchoring and/or adhesive surface for a second layer to bond to. The second layer may be used to form the nanofeature rich diffraction grating(s). In some examples, an inkjetting method of dispense (e.g., J-FIL) is used to accurately tailor LTV and/or TTV profile of incoming substrate, which can be in a roll, sheet, or wafer format for input to the system 100. The substrate 102 can also be patterned in its incoming roll form using techniques such as roll-to-roll or plate-to-roll casting, plate-to-plate casting, injection molding (e.g., soft or hard mold), stamping and blanking, and so forth. Reflectometry and/or interferometry can be used to map the LTV and/or TTV profile of the incoming substrate that is to be adjusted for optical device manufacturing. The nano-pattern of the fluid dispensed for thickness compensation and/or diffraction grating creation can be cured using ultraviolet radiation, pressure, and/or heat application to the dispensed fluid. The LTV can be adjusted using volume compensation method described above or the desired LTV profile can be molded or casted into the substrate with the final pattern through thickness compensation (e.g., planarization) achieved using a plate-to-plate or plate-to-roll configuration with the application of force or pressure prior to curing. In general, the process can be agile when coupled with in-situ metrology for LTV mapping to measure and/or compensate for a new LTV profile in the functional areas of the substrate, and more specifically where the waveguide pattern (e.g., diffraction grating) is to be imprinted.

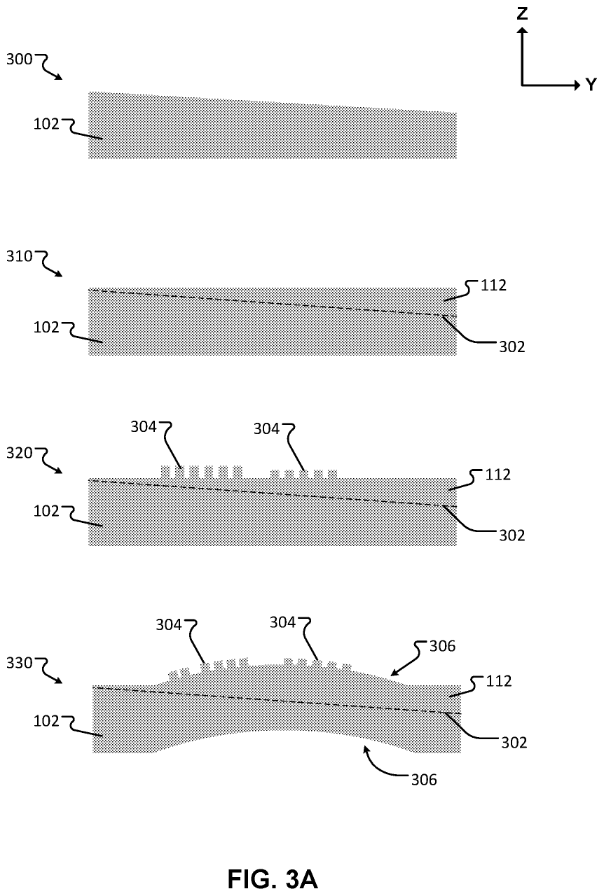

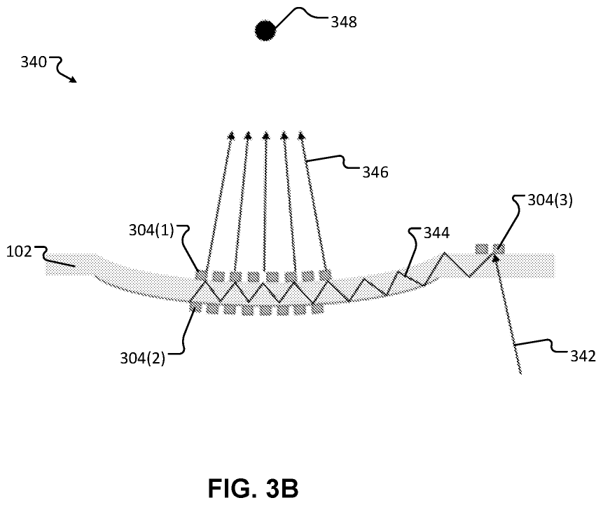

FIG. 3A depicts schematics of example optical devices, shown in a cross-sectional view. For example, such a cross-sectional view may be a view looking at the edge of the substrate 102, such that the X-direction is lengthwise along the long axis of the substrate 102, e.g., the direction along which the substrate 102 roll is unrolled, and the Y-direction is perpendicular to X across the width of the substrate 102. The Z-direction is normal to the flat (or to-be-flattened) surface(s) of the substrate 102. In instances where the substrate 102 is to be used to create a waveguide to light propagation, the resulting optical device can allow the light to propagate in the waveguide through total internal reflection (TIR) along the X-direction.

Schematic 300 shows an example profile of incoming substrate 102, prior to applying the thickness compensation techniques described herein. In this example, the incoming substrate 102 has a thickness variation in the form of a slope in the Y-direction. The substrate 102 may also exhibit other types of variation, across larger or smaller regions of the substrate surface.

Schematic 310 shows an example profile of the substrate 102 after applying the thickness compensation. As shown in this example, the original substrate 102 has been supplemented with an overlay 112 of polymer resist, such that the overall thickness variation of the combined structure is now less than the original thickness variation of the incoming substrate 102 shown in 300. A seam or boundary 302 may divide the original substrate 102 from the overlay 112 portion, and may be perceivable through close inspection of the completed optical device. However, the refraction index of the substrate 102 and the polymer resist used to create the overlay 112 may be sufficiently close so that undesired optical effects at the boundary 302 are minimized, for example to minimize reflection of light off the boundary 302 and/or refraction of light passing through the boundary 302.

Schematic 320 shows an example profile of the substrate 102 after applying the thickness compensation, and after one or more optically active regions 304, such as diffraction gratings, have been created on at least one surface of the thickness-compensated substrate 102.

Schematic 330 shows an example profile of the substrate 102 in which the thickness compensation has been applied, in which one or more optically active regions 304 have been created, and in which substrate 102 has been curved or otherwise shaped as described above. In this example, a curvature 306 has been applied to both surfaces of the substrate 102 (e.g., in a substantially matched curvature). In this configuration, the optical power of the world light is not altered, as seen through the waveguide. Instead, the curvature in this example changes the angles of the outcoupled light to provide a depth plane for the virtual light (e.g., the light conveying the graphic objects projected into the waveguide). As shown in this example, the nanogratings are arranged to substantially follow the surface of the curved substrate, and the curvature defines the focal depth where the rays exiting the waveguide converge. In other examples, the shaping may be applied to one of the surfaces of the substrate 102 and not the other. FIG. 3B illustrates this example in further detail. In this example 340, the substrate 102 has been provided with front and back curved surfaces of substantially similar curvature. The gratings 304(1) on the back surface (e.g., near the eye) and the gratings 304(2) on the front surface (e.g., facing the world) substantially follow the respective curved surfaces. Light 342 projected into the waveguide provided by substrate 102 is coupled into the waveguide by an in-coupling grating 304(3), and TIRs 344 in the waveguide until encountering gratings 304(1) and/or 304(2) that out-couple the light from the waveguide. The out-coupled light 346 is directed toward the eye 348 by virtue of the curvature.

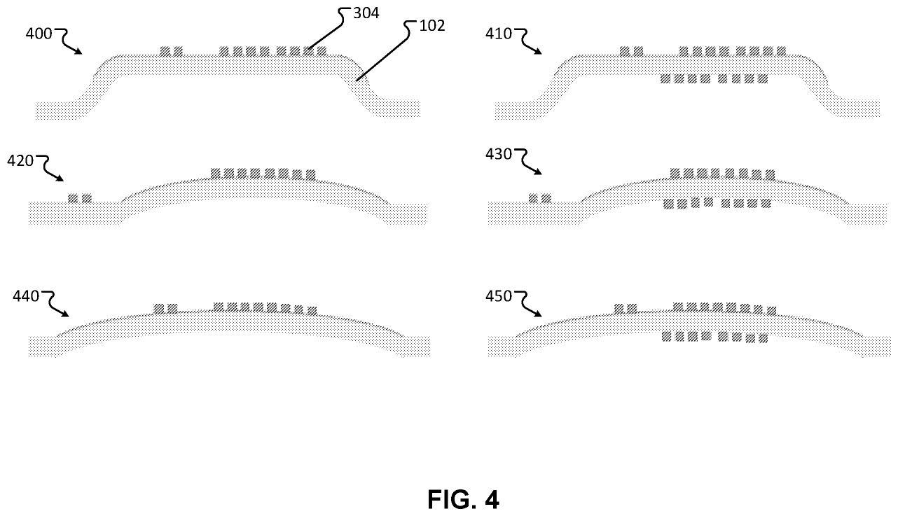

FIG. 4 depicts schematics of example optical devices. In these examples, a curved or otherwise shaped profile can be applied to the substrate 102 to provide a more desirable fit as a wearable and/or industrial design in the final product, as in examples 400 and 410. The diffraction grating(s) 304 can be created on the curved or otherwise shaped portion, as in all the examples shown. At least one diffraction grating 304 can be created on an unshaped portion of the substrate 102, as shown in examples 420 and 430. The diffraction grating(s) 304 can be created on one side of the substrate 102, as in examples 400, 420, and 440, or on both sides of the substrate 102, as in examples 410, 430, and 450.

The optical device can be curved using pressure and temperature, after the diffractive optical elements have been imprinted on the thermoplastic substrate (e.g., polycarbonate, etc.). The curvature can be applied using techniques that leave the diffraction optical elements intact post-curving. The curve profile can be created using a variable application of pressure and temperature through non-contact and/or contact elements, which can enable pressure variation for example through the use of a pressurized, heated inert gas flowing through different sized perforations in an array of cupping elements that are placed over the substrate to apply the curvature. The pressure and/or heat can be controlled to vary across any desired area of the substrate to impart a desired profile such as a curve with a constant or varying radius of curvature.

Such flexibility in processing large robust and simple eyepieces can lead to other advantages, including:
1) The waveguide pattern can be imprinted on to such substrates where the ICG can be shared across two sets of CPE's for the left and right eyes. This can be advantageous in certain designs and, when using flexible substrates, allows for curving a monolithic binocular CPE/ICG pattern. The eyepiece can be curved with respect to the bulk portion of the monolithic cut-out which is able to fit the wearable optical device.
2) Bigger displays can be created on bigger films and sheets where the view ports can consist of patterned waveguide with more than one projector in order to view a shared mixed reality experience in the far field.
3) Larger displays can be created with large patterned films or sheets with line projectors feeding light in through multiple in-coupling ports along at least one edge to create a mega-sized mixed reality display in the near field and far field but for a much broader viewing experience.

FIG. 5A shows images of example thickness measurements. Images 500 and 506 are generated through laser interferometry of the substrate 102, before and after the thickness compensation respectively. Image 504 is a photographic image of the substrate 102, showing a region 502 in which the laser interferometry was performed to measure the thickness variation across the region 502. As shown in this example, the thickness compensation technique has resulted in a considerable reduction of thickness variation in the region 502, as is visible in the result of 506 compared to the initial measurement of 500.

FIG. 5B shows images of example thickness measurements. In this example, image 510 is a photographic image of the substrate 102, and region 512 has been marked to indicate the region of interest where the eyepiece may eventually be formed through singulation. Image 520 shows the laser interferometry measurement result in the region 512, and shows substantial flattening of the thickness variation.

In FIGS. 5A and 5B, the measurement results show examples of tailored LTV on an example polycarbonate substrate ((e.g., wafer, sheet, or roll) using inkjet dispense and imprint of a ultraviolet-curable resist fluid. The fringe pattern represents the thickness variation measured using laser interferometry on the substrate 102.

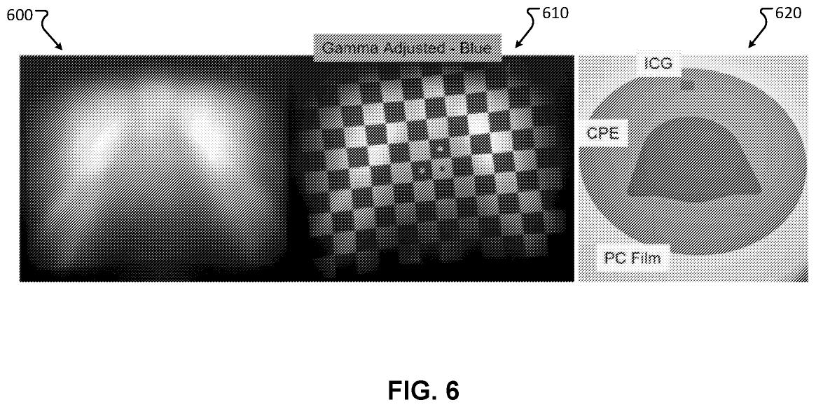

FIG. 6 show example test results of an optical device manufactured using the techniques herein. Images 600 and 610 are reticle projector images showing the performance of a thickness-adjusted waveguide. Image 600 shows a virtual image far field luminance pattern (e.g., over 50° diagonal) of an optical device manufactured using a thickness-adjusted substrate. Image 610 shows an ANSI checkerboard pattern that used to gauge sharpness and contrast of the projected pattern. Schematic 620 shows approximately the location of various components in a cross-section view of an example eyepiece. Images 600 and 610 are reticle projector images diffracted from a polycarbonate roll film waveguide with a blue light emitting diode (LED) being coupled in through a 70° field of view projector. Schematic 620 shows the physical polycarbonate film eyepiece that was fabricated and tested. The waveguide fabricated is extremely flexible and robust.

In addition to the substantial cost saving achieved by using the relatively cheap polymer substrate (e.g., compared to glass substrate), another advantage of using polymer substrate 102 is the possibility of higher field of view. For example, for an index of approximately 1.58-1.6 for polycarbonate, the field of view can be as high as 89° for a trapezoidal field of view, and 51° for a more rectangular field of view, which is a very positive result using a very inexpensive substrate modified through the thickness compensation techniques described herein.

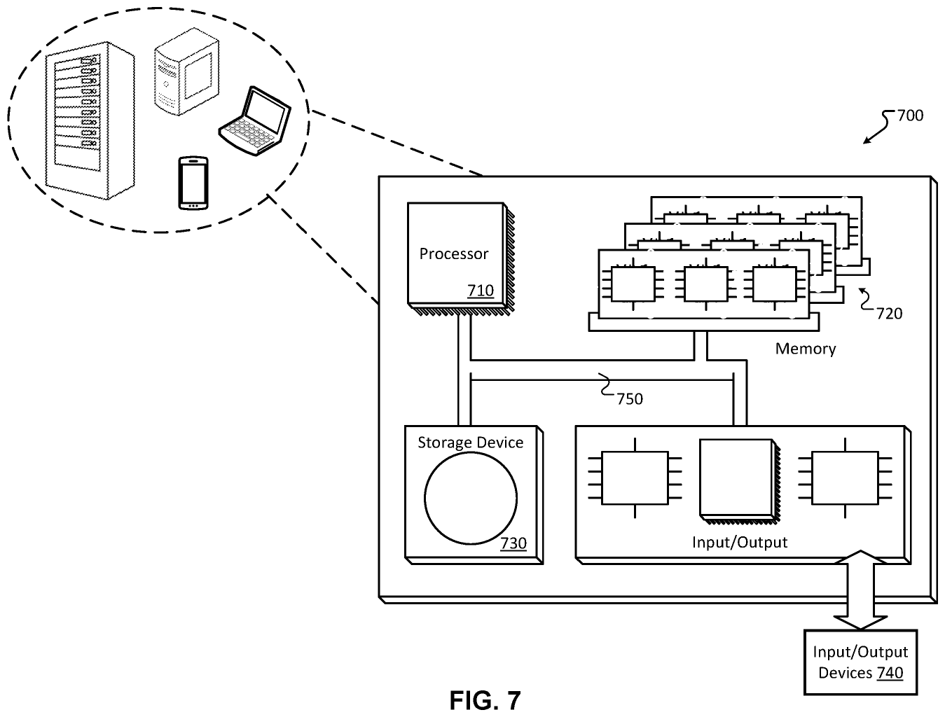

FIG. 7 illustrates a schematic diagram of an exemplary generic computer system 700. The various computing devices described herein, such as the control device 104 shown in FIG. 1, can be implemented to include one or more of the components of system 700.

The system 700 includes one or more processors 710, a memory 720, a storage device 730, and input/output device(s) 740. Each of the components 710, 720, 730, and 740 can be interconnected using one or more system busses 750. The processor(s) 710 are capable of processing instructions for execution within the system 700. The processor(s) 710 can include single-threaded processor(s) and/or multi-threaded processor(s). The processor(s) 710 are capable of processing and executing instructions stored in the memory 720 and/or on the storage device 730 to perform various operations, receiving and analyzing data input, generating data output, storing and retrieving data, presenting textual, graphical, audio, video, image(s), and/or other types of information through a user interface on the input/output device 750, and so forth.

The memory 720 stores information within the system 700. In some implementations, the memory 720 is a computer-readable medium. In some implementations, the memory 720 is a volatile memory unit. In some implementations, the memory 720 is a non-volatile memory unit.

The storage device 730 provides mass storage for the system 700. In some implementations, the storage device 730 is a computer-readable medium. In various different implementations, the storage device 730 may be a floppy disk device, a hard disk device, a solid state drive, an optical disk device, a tape device, universal serial bus stick, and/or some other suitable type of storage device.

The input/output device(s) 750 provide input/output operations for the system 700. The input/output device(s) 750 can include input devices including, but not limited to, a keyboard, a pointing device, a mouse, a touchpad, a camera, a microphone, an orientation or movement sensor (e.g., accelerometer, gyroscopic sensor, etc.), and/or a game controller. The input/output device(s) 750 can also include output devices including, but not limited to, a display, an audio speaker, a haptic actuator, a printer, and so forth.

The features described can be implemented in digital electronic circuitry, or in computer hardware, firmware, software, or in combinations of them. The apparatus can be implemented in a computer program product tangibly embodied in an information carrier, e.g., in a machine-readable storage device, for execution by a programmable processor; and method steps for the methods described herein can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any suitable programming language, including compiled or interpreted languages, and it can be deployed in any form, including as a stand-alone program or as a module, component, subroutine, library, or other unit suitable for use in a computing environment. A module is one or more computer programs and/or portion(s) of computer program(s) that is executable by one or more processors.

Suitable processors for the execution of a program of instructions include, by way of example, both general and special purpose microprocessors, and the sole processor or one of multiple processors of any kind of computer. Generally, a processor can receive instructions and data from a read-only memory or a random access memory or both. The elements of a computer are a processor for executing instructions and one or more memories for storing instructions and data. Generally, a computer will also include, or be operatively coupled to communicate with, one or more mass storage devices for storing data files. Such devices can include magnetic disks, such as internal hard disks and removable disks, magneto-optical disks, and/or optical disks. Storage devices suitable for tangibly embodying computer program instructions and data include any suitable form of non-volatile memory, including by way of example semiconductor memory devices, such as erasable programmable read-only memory (EPROM), electrically erasable programmable read-only memory (EEPROM), flash memory devices, magnetic disks such as internal hard disks and removable disks, magneto-optical disks, and compact disk read-only memory (CD-ROM) and digital video disk read-only memory (DVD-ROM) disks. The processor and the memory can be supplemented by or incorporated into one or more application-specific integrated circuits (ASICs).

To provide for interaction with a user, the features can be implemented on a system having a input/output device(s), such as a display device. Display devices can include any suitable type of display, such as cathode ray tube (CRT), liquid crystal display (LCD), and so forth, for displaying information to the user. Input device(s) such as a keyboard and/or a pointing device such as a mouse or a rail trackball can enable user input to the system.

The features can be implemented in a computer system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include, e.g., a local area network (LAN), a wide area network (WAN), and the computers and networks forming the Internet.

The computer system can include clients and servers. A client and server are generally remote from each other and typically interact through a network, such as those discussed herein. The relationship of client and server arises by virtue of computer programs running on the respective computers and having a client-server relationship to each other. The servers may be part of a cloud, which may include ephemeral aspects.

While this disclosure contains many specific implementation details, these should not be construed as limitations on the scope of any implementation of the present disclosure or of what may be claimed, but rather as descriptions of features specific to example implementations. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. In addition, the processes depicted in the figures do not necessarily require the particular order shown, or sequential order, to achieve desirable results. In certain implementations, multitasking and parallel processing may be advantageous.

While various implementations of the present invention have been described herein, it should be understood that they have been described as examples. Many variations and modifications may be apparent to those skilled in the art upon reading the specification. The breadth and scope of the present invention is not limited by the examples described herein, and can be interpreted broadly to include such variations and modifications. The described implementations and other such implementations are within the scope of the following claims.

1. A method performed by a system for manufacturing optical devices, the method comprising:
measuring variation in a thickness of at least a portion of a substrate that is provided as input to the system;
based on the measured variation in the thickness of the substrate, determining a drop pattern for applying a fluid to at least the portion of the substrate, wherein the drop pattern reduces the variation in the thickness in at least the portion of the substrate; and
applying the drop pattern to at least the portion of the substrate, including dispensing the fluid onto the substrate according to the drop pattern and curing the fluid.

2. The method of claim 1, wherein the substrate is composed of a polymer, glass, or one or more of polycarbonate, polyethylene terephthalate, or polyethylene naphthalate.

3. (canceled)

4. (canceled)

5. (canceled)

6. The method of claim 1, wherein the fluid and the substrate have substantially a same refractive index.

7. The method of claim 1, wherein curing the fluid includes one or more of applying ultraviolet radiation to the dispensed fluid, or applying heat to the dispensed fluid.

8. The method of claim 1, wherein determining the drop pattern includes selecting the drop pattern from a plurality of different drop patterns stored in a drop pattern library, wherein each of the plurality of different drop patterns corresponds to a respective variation profile, and wherein the drop pattern selected based on its correspondence to the variation profile corresponding to the measured variation.

9. The method of claim 1, wherein measuring the variation in the thickness of at least the portion of the substrate includes performing at least one of interferometry or reflectometry to measure the variation.

10. (canceled)

11. The method of claim 1, further comprising:
creating one or more diffraction gratings on the portion of the substrate; and
singulating the substrate to separate the portion as an optical device, wherein the one or more diffraction gratings include one or more of an in-coupling grating (ICG), an orthogonal pupil expander (OPE), an exit pupil expander (EPE), or a combined pupil expander (CPE).

12. (canceled)

13. The method of claim 11, wherein creating the one or more diffraction gratings is performed by the system prior to measuring the variation in the thickness and applying the drop pattern.

14. (canceled)

15. The method of claim 11, wherein measuring the variation in the thickness, applying the drop pattern, creating the one or more diffraction gratings, and singulating the substrate are performed by the system as inline operations on the substrate input to the system.

16. The method of claim 11, wherein creating the one or more diffraction gratings and applying the drop pattern are performed by the system in a same operation of dispensing the fluid, and curing the dispensed fluid.

17. The method of claim 11, further comprising shaping at least one surface of the portion of the substrate into a curved shape, by applying one or more of pressure, heat, or a surface contact mold to the portion of the substrate.

18. The method of claim 11, wherein the drop pattern is applied to a first side of the portion of the substrate, and the one or more diffraction gratings are created on a second side of the portion of the substrate that is opposite the first side.

19. The method of claim 11, wherein the drop pattern is applied to a same side of the portion of the substrate as the one or more diffraction gratings.

20. The method of claim 1, wherein the substrate is input to the system in a form comprising one or more of a roll, a sheet, a web, a web roll, or a wafer.

21. An optical device, comprising:
a substrate that exhibits a first thickness variation across a region of the optical device; and
an overlay applied to the region of the optical device, the overlay exhibiting a second thickness variation that compensates for the first thickness variation such that a combined thickness variation in the region is less than the first thickness variation.

22. The optical device of claim 21, wherein the substrate is composed of a polymer, a glass, or one or more of polycarbonate, polyethylene terephthalate, or polyethylene naphthalate, and the overlay is composed of a polymer resist.

23. (canceled)

24. (canceled)

25. (canceled)

26. The optical device of claim 21, wherein the substrate and the overlay have substantially a same refractive index.

27. The optical device of claim 21, further comprising one or more diffraction gratings on at least one surface of the optical device, wherein the one or more diffraction gratings include one or more of an in-coupling grating (ICG), an orthogonal pupil expander (OPE), an exit pupil expander (EPE), or a combined pupil expander (CPE).

28. (canceled)

29. The optical device of claim 21, wherein at least one surface of the optical device is curved.

30. The optical device of claim 21, wherein the first thickness variation is a local thickness variation or a total thickness variation.
